(19) United States
(12) Patent Application Publication
(10) Pub. No.: US 2022/0336676 A1
(43) Pub. Date: Oct. 20, 2022

(54) DISPLAY SUBSTRATE, DISPLAY PANEL AND DISPLAY DEVICE

(71) Applicants: Chengdu BOE Optoelectronics Technology Co.,Ltd., Chengdu, Sichuan Province (CN); BOE Technology Group Co., Ltd., Beijing (CN)

(72) Inventors: Yao HUANG, Beijing (CN); Tianyi CHENG, Beijing (CN); Weiyun HUANG, Beijing (CN); Yue LONG, Beijing (CN); Benlian WANG, Beijing (CN)

(21) Appl. No.: 17/417,492

(22) PCT Filed: Sep. 18, 2020
(86) PCT No.: PCT/CN2020/116152

§ 371 Date: Jun. 23, 2021

(51) Int. Cl. H01L 29/786; H01L 27/32

(52) U.S. Cl. CPC H01L 29/78675; H01L 27/3246; H01L 27/3258; H01L 29/7869

(57) ABSTRACT

This application can provide a display substrate, a display panel and a display device. The display substrate includes a top-gate oxide thin film transistor and a top-gate low temperature poly-silicon thin film transistor located above a base substrate. The top-gate low temperature poly-silicon thin film transistor includes a first active layer and a first gate, stacked above the base substrate. The display substrate further includes a first gate insulating layer, disposed between the first active layer and the first gate; a second gate insulating layer, disposed between the first gate insulating layer and the first gate; and a second gate, disposed between the first gate insulating layer and the second gate insulating layer.

### CROSS REFERENCE TO RELATED APPLICATIONS

This application is a national phase entry under 35 U.S.C. § 371 of International Application No. PCT/CN2020/116152, filed on Sep. 18, 2020, the entire content of which is incorporated herein by reference.

### FIELD

The present disclosure relates to the field of display, in particular to a display substrate, a display panel and a display device.

### BACKGROUND

A low temperature polycrystalline oxide (LTPO) substrate is a novel display substrate, which has the advantages of a low temperature poly-silicon (LTPS) substrate and an oxide substrate, and is the main development direction of display substrates in the future. The LTPS substrate refers to a display substrate in which a thin film transistor (TFT) in a display unit is an LTPS TFT, the oxide substrate refers to a display substrate in which a TFT in a display unit is an oxide TFT, the LTPO substrate refers to a display substrate in which an LTPS TFT and an oxide TFT are both included in each display unit, and display units are also called sub-pixels.

### SUMMARY

A display substrate provided by an embodiment of the present disclosure includes:

a base substrate;

a top-gate oxide TFT, located above the base substrate;

a top-gate LTPS TFT, located above the base substrate and including a first active layer and a first gate disposed laminated above the base substrate;

a first gate insulating layer, disposed between the first active layer and the first gate;

a second gate insulating layer, disposed between the first gate insulating layer and the first gate; and

a second gate, disposed between the first gate insulating layer and the second gate insulating layer, where an orthographic projection of the second gate on the base substrate does not overlap with an orthographic projection of the top-gate LTPS TFT on the base substrate, and the orthographic projection of the second gate on the base substrate covers an orthographic projection of the top-gate oxide TFT on the base substrate.

In one embodiment, in the display substrate provided by the embodiment of the present disclosure, a material of the first gate insulating layer is silicon oxide, and a material of the second gate insulating layer is silicon oxide; or a material of the first gate insulating layer is silicon oxide, and a material of the second gate insulating layer silicon nitride.

In one embodiment, in the display substrate provided by the embodiment of the present disclosure, the top-gate oxide TFT includes: a second active layer and a third gate disposed laminated above the base substrate, and a first source and a first drain disposed on a side, away from the base substrate, of the third gate, where the first source and the first drain are electrically connected with the second active layer respectively, and the orthographic projection of the second gate on the base substrate covers an orthographic projection of the second active layer on the base substrate; and

the top-gate LTPS TFT further includes a second source and a second drain disposed on a side, away from the base substrate, of the first gate, where the second source and the second drain are electrically connected with the first active layer respectively,

and the first source and the first drain are disposed on the same layer as the second source and the second drain.

In one embodiment, the display substrate provided by the embodiment of the present disclosure further includes: a first buffer layer disposed between the first gate and the second active layer, and a second buffer layer disposed between the first buffer layer and the second active layer, where a material of the first buffer layer is silicon nitride, and a material of the second buffer layer is silicon oxide.

In one embodiment, the display substrate provided by the embodiment of the present disclosure further includes a third gate insulating layer disposed between the second active layer and the third gate, where a material of the third gate insulating layer is silicon oxide.

In one embodiment, the display substrate provided by the embodiment of the present disclosure further includes: an interlayer insulating layer disposed between the third gate and the first source, a first flat layer disposed on a side, away from the base substrate, of the first source, a source-drain metal layer disposed on a side, away from the base substrate, of the first flat layer, a second flat layer disposed on a side, away from the base substrate, of the source-drain metal layer, and an anode disposed on a side, away from the base substrate, of the second flat layer, where

the source-drain metal layer is electrically connected with the second drain through a via hole penetrating the first flat layer, and the anode is electrically connected with the source-drain metal layer through a via hole penetrating the second flat layer.

In one embodiment, the display substrate provided by the embodiment of the present disclosure further includes: a pixel definition layer disposed on a side, away from the base substrate, of the anode, and a spacer layer disposed on the pixel definition layer.

In one embodiment, the display substrate provided by the embodiment of the present disclosure further includes: a barrier layer disposed between the base substrate and the first active layer, and a third buffer layer disposed between the barrier layer and the first active layer.

Correspondingly, an embodiment of the present disclosure further provides a display panel, including the above display substrate provided by the embodiment of the present disclosure.

Correspondingly, an embodiment of the present disclosure further provides a display device, including the above display panel provided by the embodiment of the present disclosure.

### BRIEF DESCRIPTION OF THE DRAWINGS

FIG. 1 is a schematic diagram of a partial cross-sectional structure of a display substrate provided by an embodiment of the present disclosure;

FIG. 2 is a schematic diagram of a partial cross-sectional structure of another display substrate provided by an embodiment of the present disclosure; and

FIG. 3 is a structural schematic diagram of a display device provided by an embodiment of the present disclosure.

### DETAILED DESCRIPTION OF THE EMBODIMENTS

In order to make the objective, technical solutions and advantages of the embodiments of the disclosure clearer, the technical solutions of the embodiments of the disclosure will be described clearly and completely with reference to the drawings of the embodiments of the disclosure. Obviously, the described embodiments are only part of the embodiments of the disclosure, not all the embodiments. Besides, the embodiments in the disclosure and the features in the embodiments may be combined with each other without conflict. Based on the embodiments described in the disclosure, all other embodiments obtained by those of ordinary skill in the art without creative efforts are within the scope of protection of the disclosure.

Unless otherwise defined, technical terms or scientific terms used in the disclosure shall have the ordinary meaning understood by those with ordinary skills in the field to which the disclosure belongs. Words like “comprise” or “include” used in the present disclosure mean that the elements or articles appearing before the words cover the elements or articles listed after the words and their equivalents, and do not exclude other elements or articles. Words like “connect” are not limited to physical or mechanical connection, but may include electrical connection, whether direct or indirect. “Inner”, “outer”, “up” and “down” are only used to indicate the relative positional relationship. When the absolute position of a described object changes, the relative positional relationship may also change accordingly.

It should be noted that the sizes and shapes of the figures in the drawings do not reflect true proportions, and are only for the purpose of schematically illustrating the contents of the disclosure. Moreover, the same or similar reference numerals throughout refer to the same or similar elements or elements having the same or similar functions.

A display substrate is a main component of a display device, and includes a base substrate and display units arranged on the base substrate. The display unit includes a thin film transistor (TFT). An LTPS substrate refers to a display substrate in which a TFT in the display unit is an LTPS TFT, and an oxide substrate refers to a display substrate in which a TFT in the display unit is an oxide TFT. The mobility of a poly-silicon active layer is large, which makes the leakage current (I_{off}) of the LTPS TFT large, and the power consumption of the LTPS substrate under low frequency drive is large, so it is difficult to maintain a static black image, and image quality is poor. In addition, in order to develop the gray scale better, in the LTPS base substrate, a channel of a driver thin film transistor (DTFT) needs to be made very long, which makes it difficult to achieve a high resolution of the LTPS substrate. The resolution refers to pixel per inch (PPI). In addition, the hysteresis of a poly-silicon active layer is large, so the LTPS substrate is prone to the problem of afterimage. The mobility of an oxide active layer is small, so that the I_{off} of the oxide TFT is small, and the power consumption of the oxide base substrate under low frequency drive is small, thereby maintaining the static black image better and improving the image quality. In addition, in the oxide substrate, the gray scale can be better developed without making the channel of the DTFT very long, and high PPI can be realized. Besides, the hysteresis of the oxide active layer is small, and the oxide substrate is not prone to the problem of afterimage. Furthermore, the uniformity of the oxide TFT is better than that of the LTPS TFT.

According to the above description, the oxide process can make up for some shortcomings of the LTPS process. The LTPS process and the oxide process have their own advantages and disadvantages, so the combination of the LTPS process and the oxide process will be very competitive. An LTPO process, which is generated by combining the LTPS process with the oxide process, is likely to be used in the development of high-end products in the future.

A display substrate based on the LTPO process is an LTPO base substrate, in which each display unit comprises an LTPS TFT and an oxide TFT.

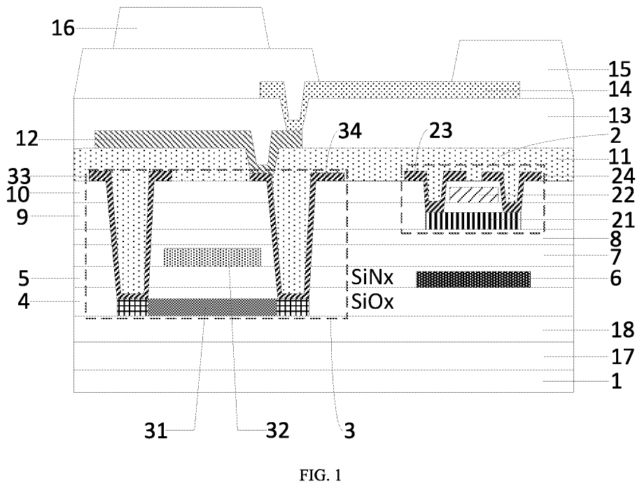

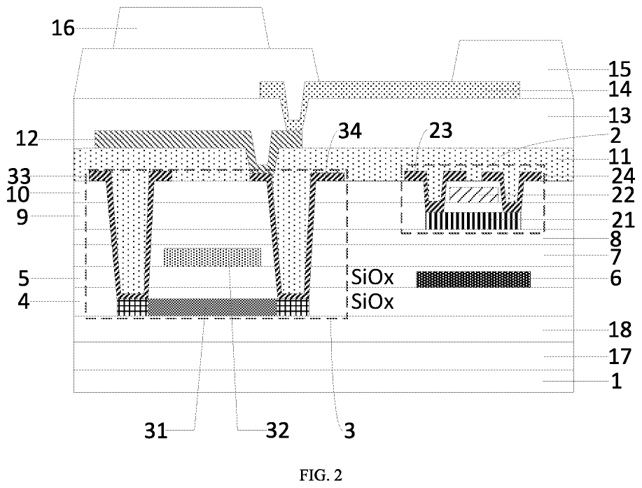

A display substrate provided by an embodiment of the present disclosure, as shown in FIGS. 1 and 2, includes:

a base substrate 1;

a top-gate oxide TFT 2, located above the base substrate 1;

a top-gate LTPS TFT 3, located above the base substrate 1, where the top-gate LTPS TFT 3 includes a first active layer 31 and a first gate 32 which are stacked above the base substrate 1, and the embodiment of the present disclosure is schematically illustrated by assuming that an orthographic projection of the top-gate LTPS TFT 3 on the base substrate 1 does not overlap with an orthographic projection of the top-gate oxide TFT 2 on the base substrate 1;

a first gate insulating layer 4, disposed between the first active layer 31 and the first gate 32;

a second gate insulating layer 5, disposed between the first gate insulating layer 4 and the first gate 32; and

a second gate 6, disposed between the first gate insulating layer 4 and the second gate insulating layer 5, where an orthographic projection of the second gate 6 on the base substrate 1 does not overlap with the orthographic projection of the top-gate LTPS TFT 3 on the base substrate 1, and the orthographic projection of the second gate 6 on the base substrate 1 covers the orthographic projection of the top-gate oxide TFT 2 on the base substrate 1.

According to the display substrate provided by the embodiment of the present disclosure, the first gate insulating layer 4 and the second gate insulating layer 5 are arranged between the first active layer 31 and the first gate 32 of the top-gate LTPS TFT 3, and the second gate 6 covering the top-gate oxide TFT 2 is arranged between the first gate insulating layer 4 and the second gate insulating layer 5, so that the thickness of the gate insulating layers of the top-gate LTPS TFT 3 may be increased without increasing the overall thickness of a display module, thereby reducing the I_{off} of the top-gate LTPS TFT 3, increasing characteristic uniformity and improving image quality. In addition, increasing the thickness of the gate insulating layers of the top-gate LTPS TFT 3 may reduce the interelectrode capacitance of the top-gate LTPS TFT 3, thereby reducing the gate load, reducing the RC delay on a gate line and further prolonging the charging time of the gate line.

It should be noted that the description that the orthographic projection of the second gate 6 on the base substrate 1 covers the orthographic projection of the top-gate oxide TFT 2 on the base substrate 1 means that the orthographic projection of the second gate 6 on the base substrate 1 can at least completely block the orthographic projection of the top-gate oxide TFT 2 on the base substrate 1, that is, the area of the orthographic projection of the second gate 6 on the base substrate 1 is greater than or equal to that of the orthographic projection of the top-gate oxide TFT 2 on the base substrate 1.

In some embodiments, a material of the gate insulating layers generally includes silicon oxide or silicon nitride. Silicon oxide has few defects and may improve carrier mobility, and silicon nitride has great insulation performance. Therefore, in the above display substrate provided by the embodiment of the disclosure, the material of the first gate insulating layer close to the first active layer may be silicon oxide to improve the carrier mobility of the top-gate LTPS TFT, and the material of the second gate insulating layer may be silicon oxide or silicon nitride. For example, as shown in FIG. 1, the material of the first gate insulating layer 4 is silicon oxide, and the material of the second gate insulating layer 5 is silicon nitride. As shown in FIG. 2, the material of the first gate insulating layer 4 is silicon oxide, and the material of the second gate insulating layer 5 is also silicon oxide.

In some embodiments, in the above display substrate provided by the embodiment of the present disclosure, as shown in FIGS. 1 and 2, the top-gate oxide TFT 2 includes: a second active layer 21 and a third gate 22 which are stacked above the base substrate 1, and a first source 23 and a first drain 24 which are disposed on a side, away from the base substrate 1, of the third gate 22, where the first source 23 and the first drain 24 are electrically connected with the second active layer 21. Since the second active layer 21 of the top-gate oxide TFT 2 is made of an oxide material, and its performance may be damaged by external ambient light, the present disclosure arranges the orthographic projection of the second gate 6 on the base substrate 1 to cover the orthographic projection of the second active layer 21 on the base substrate 1, so that the second gate 6 provided by the embodiment of the present disclosure can serve to protect the second active layer 21 of the top-gate oxide TFT 2 from external ambient light, thereby improving the performance of the top-gate oxide TFT 2.

The top-gate LTPS TFT 3 further includes a second source 33 and a second drain 34 which are disposed on a side, away from the base substrate 1, of the first gate 32, where the second source 33 and the second drain 34 are electrically connected with the first active layer 31, respectively. In some embodiments, the portions, electrically connected with the second source 33 and the second drain 34, of the first active layer 31 are conductive regions, which may be formed by ion doping.

The first source 23 and the first drain 24 are disposed on the same layer as the second source 33 and the second drain 34. In this way, the patterns of the second source 33 and the second drain 34 and the patterns of the first source 23 and the first drain 24 may be formed through one-time patterning simply by changing the original patterns when forming the first source 23 and the first drain 24, and a process for separately preparing the second source 33 and the second drain 34 is not required, so that the preparation process may be simplified, the production cost may be saved, and the production efficiency may be improved.

In some embodiments, as shown in FIGS. 1 and 2, the third gate 22 is one gate of the top-gate oxide TFT 2, and the second gate 6 may be used as the other gate of the top-gate oxide TFT 2, so that the top-gate oxide TFT 2 is a TFT with a double-gate structure which can reduce the I_{off} of the TFT and improve the stability of a circuit structure where the TFT is located.

It should be noted that the description that the orthographic projection of the second gate 6 on the base substrate 1 covers the orthographic projection of the second active layer 21 on the base substrate 1 means that the orthographic projection of the second gate 6 on the base substrate 1 can at least completely block the orthographic projection of the second active layer 21 on the base substrate 1, that is, the area of the orthographic projection of the second gate 6 on the base substrate 1 is greater than or equal to that of the orthographic projection of the second active layer 21 on the base substrate 1.

In some embodiments, as shown in FIGS. 1 and 2, the display substrate provided by the embodiment of the present disclosure further includes: a first buffer layer 7 disposed between the first gate 32 and the second active layer 21, and a second buffer layer 8 disposed between the first buffer layer 7 and the second active layer 21. A material of the first buffer layer 7 may be silicon nitride, and a material of the second buffer layer 8 may be silicon oxide. The first buffer layer 7 and the second buffer layer 8 may have a flattening function and improve the adhesion between subsequent films and the base substrate 1.

In some embodiments, as shown in FIGS. 1 and 2, the display substrate provided by the embodiment of the present disclosure further includes a third gate insulating layer 9 disposed between the second active layer 21 and the third gate 22. A material of the third gate insulating layer 9 may be silicon oxide.

In some embodiments, as shown in FIGS. 1 and 2, the display substrate provided by the embodiment of the present disclosure further includes: an interlayer insulating layer 10 disposed between the third gate 22 and the first source 23, a first flat layer 11 disposed on a side, away from the base substrate 1, of the first source 23, a source-drain metal layer 12 disposed on a side, away from the base substrate 1, of the first flat layer 11, a second flat layer 13 disposed on a side, away from the base substrate 1, of the source-drain metal layer 12, and an anode 14 disposed on a side, away from the base substrate 1, of the second flat layer 13.

The source-drain metal layer 12 is electrically connected with the second drain 34 through a via hole penetrating the first flat layer 11, and the anode 14 is electrically connected with the source-drain metal layer 12 through a via hole penetrating the second flat layer 13.

In some embodiments, as shown in FIGS. 1 and 2, the display substrate provided by the embodiment of the present disclosure further includes a pixel definition layer 15 disposed on a side, away from the base substrate 1, of the anode 14, and a spacer layer 16 disposed on the pixel definition layer 15. The pixel definition layer 15 has a plurality of pixel openings, and part of the anode 14 is exposed through each pixel opening. A luminescent layer and a cathode which are disposed on a side, away from the base substrate 1, of the anode 14, and other functional film layers such as a packaging layer are fabricated later, which will not be described in detail here. The spacer layer 16 plays a supporting role when the display substrate and a glass cover plate are boned to each other subsequently.

In some embodiments, anode voltage is input to the anode and cathode voltage is input to the cathode through the TFT, that is, driven by external voltage, electrons injected through the cathode and holes injected through the anode are compounded in the luminescent layer to form electron-hole pairs at a bound level, i.e., excitons, and exciton radiation excites photons to generate visible light.

In some embodiments, as shown in FIGS. 1 and 2, the display substrate provided by the embodiment of the present disclosure further includes: a barrier layer 17 disposed between the base substrate 1 and the first active layer 31, and a third buffer layer 18 disposed between the barrier layer 17 and the first active layer 31. The barrier layer 17 is for blocking external water vapor, and the third buffer layer 18 is for improving the adhesion between the films to be manufactured later and the base substrate 1. A material of the barrier layer 17 may be one or a combination of silicon oxide and silicon nitride, and a material of the third buffer layer 18 may be silicon oxide.

Of course, the display device provided by the embodiment of the present disclosure may further include other functional films well known to those skilled in the art, which will not be described in detail here.

Based on the same inventive concept, an embodiment of the present disclosure further provides a display panel, including the display substrate provided by the embodiment of the present disclosure.

In some embodiments, the display panel provided by the embodiment of the present disclosure is an organic light-emitting display panel.

Based on the same inventive concept, an embodiment of the present disclosure further provides a display device, including the above display panel provided by the embodiment of the present disclosure. The principle of the display device for solving problems is similar to that of the aforementioned display substrate, so the display device may be implemented with reference to the implementation of the aforementioned display substrate, which will not be elaborated here.

In some embodiments, the display device provided by the embodiment of the present disclosure may be an organic light-emitting display device.

In some embodiments, the display device provided by the embodiment of the present disclosure may be an all-screen display device or a flexible display device, which is not limited here.

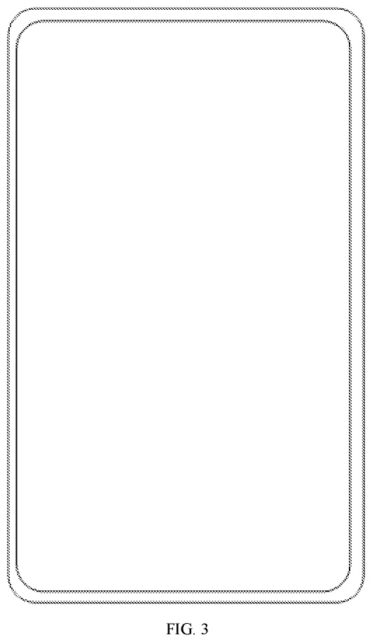

In some embodiments, the display device provided by the embodiment of the present disclosure may be an all-screen mobile phone as shown in FIG. 3. Of course, the display device provided by the embodiment of the present disclosure may also be any product or component with a display function such as a tablet computer, a television, a display, a notebook computer, a digital photo frame, and a navigator. Other essential components of the display device should be understood by those of ordinary skill in the art, and are not described in detail herein, nor should they be taken as limitations to the disclosure.

According to the display substrate, the display panel and the display device provided by the embodiments of the present disclosure, two gate insulating layers, the first gate insulating layer and the second gate insulating layer, are arranged between the first active layer and the first gate of the top-gate LTPS TFT, and the second gate covering the top-gate oxide TFT is arranged between the first gate insulating layer and the second gate insulating layer, so that the thickness of the gate insulating layers of the top-gate LTPS TFT may be increased without increasing the overall thickness of a display module, thereby reducing the I_{off} of the top-gate LTPS TFT, increasing characteristic uniformity and improving display image quality. In addition, increasing the thickness of the gate insulating layers of the top-gate LTPS TFT may reduce the interelectrode capacitance of the top-gate LTPS TFT, thereby reducing the gate load, reducing the RC delay on a gate line and further prolonging the charging time of the gate line.

Although the preferred embodiments of the present disclosure have been described, those skilled in the art may make additional changes and modifications to these embodiments once they know the basic inventive concepts. Therefore, the appended claims are intended to be interpreted as including the preferred embodiment and all changes and modifications that fall within the scope of the disclosure.

Obviously, those skilled in the art may make various changes and modifications to the embodiments of the disclosure without departing from the spirit and scope of the embodiments of the disclosure. Thus, the disclosure is also intended to include such modifications and variations if they fall within the scope of the claims of the disclosure and their equivalents.

1. A display substrate, comprising:
a base substrate;
a top-gate oxide thin film transistor (TFT), located above the base substrate;
a top-gate low temperature poly-silicon (LTPS) TFT, located above the base substrate and comprising a first active layer and a first gate disposed laminated above the base substrate;
a first gate insulating layer, disposed between the first active layer and the first gate;
a second gate insulating layer, disposed between the first gate insulating layer and the first gate; and
a second gate, disposed between the first gate insulating layer and the second gate insulating layer, wherein:
an overlapping area of an orthographic projection of the second gate on the base substrate and an orthographic projection of the top-gate LTPS TFT on the base substrate is 0, and
the orthographic projection of the second gate on the base substrate covers an orthographic projection of the top-gate oxide TFT on the base substrate.

2. The display substrate of claim 1, wherein:
a material of the first gate insulating layer is silicon oxide, and a material of the second gate insulating layer is silicon oxide; or
a material of the first gate insulating layer is silicon oxide, and a material of the second gate insulating layer is silicon nitride.

3. The display substrate of claim 1, wherein the top-gate oxide TFT comprises:
a second active layer and a third gate disposed laminated above the base substrate, and
a first source and a first drain disposed on a side, away from the base substrate, of the third gate, the first source and the first drain being electrically connected with the second active layer respectively, and the orthographic projection of the second gate on the base substrate covers an orthographic projection of the second active layer on the base substrate;
wherein the top-gate LTPS TFT further comprises:
a second source and a second drain disposed on a side, away from the base substrate, of the first gate, the second source and the second drain being electrically connected with the first active layer respectively, and
wherein the first source and the first drain are disposed on the same layer as the second source and the second drain.

4. The display substrate of claim 3, further comprising:
a first buffer layer disposed between the first gate and the second active layer, and
a second buffer layer disposed between the first buffer layer and the second active layer,
wherein a material of the first buffer layer is silicon nitride, and a material of the second buffer layer is silicon oxide.

5. The display substrate of claim 3, further comprising:
a third gate insulating layer disposed between the second active layer and the third gate, wherein a material of the third gate insulating layer is silicon oxide.

6. The display substrate of claim 3, further comprising:
an interlayer insulating layer disposed between the third gate and the first source,
a first flat layer disposed on a side, away from the base substrate, of the first source,
a source-drain metal layer disposed on a side, away from the base substrate, of the first flat layer,
a second flat layer disposed on a side, away from the base substrate, of the source-drain metal layer, and
an anode disposed on a side, away from the base substrate, of the second flat layer,
wherein the source-drain metal layer is electrically connected with the second drain through a via hole penetrating the first flat layer, and the anode is electrically connected with the source-drain metal layer through a via hole penetrating the second flat layer.

7. The display substrate of claim 6, further comprising:
a pixel definition layer disposed on a side, away from the base substrate, of the anode, and
a spacer layer disposed on the pixel definition layer.

8. The display substrate of claim 1, further comprising:
a barrier layer disposed between the base substrate and the first active layer, and
a third buffer layer disposed between the barrier layer and the first active layer.

9. A display panel, comprising the display substrate of.

10. A display device, comprising the display panel of claim 9.
